(19) United States
(12) Patent Application Publication
(10) Pub. No.: US 2008/0149307 A1
(43) Pub. Date: Jun. 26, 2008

(54) Heat transfer duct fastening structure

(75) Inventors: Tung-Hsing Tsou, Hsinchu County (TW); Cheng-Kang Wen, Hsinchu County (TW); Chang-Lung Li, Hsinchu County (TW)

Correspondence Address: Joe McKinney Muncy, PO Box 1364, Fairfax, VA, 22038-1364, US

(73) Assignee: CHENG HOME ELECTRONICS CO., LTD.

(21) Appl. No.: 11/641,706

(22) Filed: Dec. 20, 2006

(51) Int. Cl. H05K 7/20

(52) U.S. Cl. 165/80.3; 165/104.33; 361/700

(57) ABSTRACT

A heat transfer duct fastening structure aims to firmly mount a heat transfer duct onto a heat conductive base to increase heat transfer efficiency and facilitate heat dissipating of an electronic device and prevent the electronic device from being damaged at high temperature. The structure includes the base and the heat transfer duct. The base is a good heat conductive element and has a coupling portion to receive the heat transfer duct. The heat transfer duct and the inner wall of the coupling portion are soldered together through a soldering paste. Thus heat generated by the electronic device can be transmitted through the base and heat transfer duct and released to the air.

### FIELD OF THE INVENTION

The present invention relates to a heat transfer structure and particularly to a heat transfer duct fastening structure.

### BACKGROUND OF THE INVENTION

Heat transfer duct is widely used for heat dissipating of electronic devices. It is a low pressure and closed metal tube containing a desired amount of heat transfer fluid such as pure water, acetone or the like. It has an inner wall which allows the heat transfer fluid to adsorb thereon, and the fluid can move to a heat source through capillary action. As the heat transfer duct is in a low pressure condition, when one end is heated the heat transfer fluid is easily vaporized. The vaporized gas enters the interior space of the duct where the temperature is lower, and the heat transfer fluid is condensed to become liquid. The interior space of the heat transfer duct is a very small. The condensed heat transfer fluid flows back to the heating end of the heat transfer duct because of the capillary action. Thus a continuous circulation is generated to transfer heat.

As previously discussed, the heat transfer duct is a tubular structure and difficult to be coupled with the general electronic device. At present a base is commonly provided as a heat exchange interface. The base is a good heat transfer element and can effectively transfer heat generated by the electronic device to the heat transfer duct to achieve heat dissipating effect. One of the conventional techniques to couple the base and the heat transfer duct is forming an elongated trough on the base to hold the heat transfer duct in a transverse manner, then they are soldered together or fastened through an external fastening element. As the space between the trough and the heat transfer duct is small, controlling the amount of soldering paste to be used during soldering operation is difficult. Soldering paste overflow or deficit frequently occurs. On the other hand, fastening by the external fastening element also has its share of problems. As the contact area between the base and heat transfer duct is small, heat transfer rate between the two is limited. Another technique for coupling the base and heat transfer duct is forming a small orifice on the base to receive the heat transfer duct. The insertion end of the heat transfer duct is extended outside the bottom of the base and has to be removed by grinding. As the heat transfer duct is vertical to the base, contact area between the heat transfer duct and the air increases significantly, and the heat dissipating efficiency also increases. But the heat transfer duct is a small hollow tube, to trim the bottom end of the base by grinding tends to damage the heat transfer duct.

### SUMMARY OF THE INVENTION

The primary object of the present invention is to firmly fasten a heat transfer duct to a base to achieve desired heat dissipating effect. To achieve the foregoing object the base of the invention has a coupling portion to receive the heat transfer duct, and a soldering paste is applied by soldering to form a tight coupling between the heat transfer duct and the base. Such an approach can prevent the heat transfer duct from toppling. Heat transfer efficiency between the base and the heat transfer duct also increases. Moreover, the heat transfer duct can also be coupled with one or more heat dissipating fin to further enhance heat dissipating efficiency.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a perspective view of the heat transfer duct fastening structure of the invention.

FIG. 2 is a sectional view of the heat transfer duct fastening structure of the invention.

FIG. 3 is a sectional view of a second embodiment of the heat transfer duct fastening structure of the invention.

FIG. 4 is a perspective view of a third embodiment of the heat transfer duct fastening structure of the invention.

### DETAILED DESCRIPTION OF THE PREFERRED EMBODIMENTS

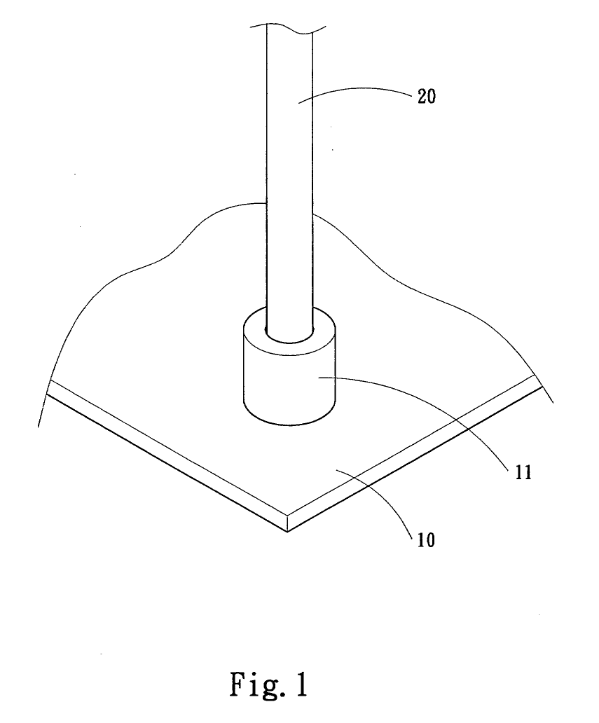

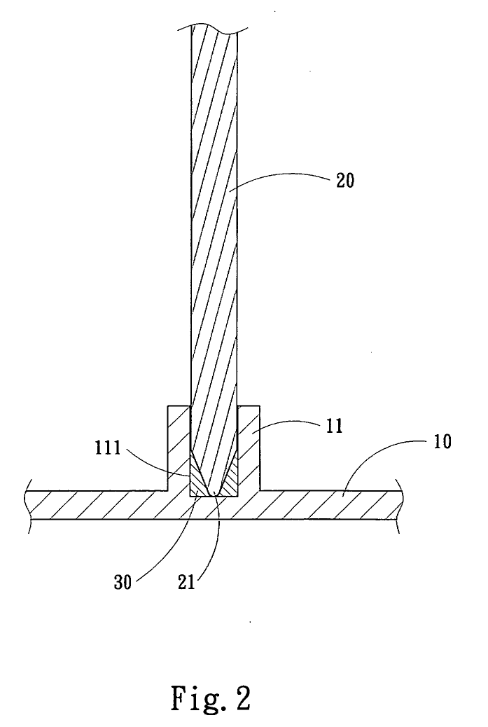

Please refer to FIGS. 1 and 2, the heat transfer duct fastening structure according to the invention includes a base 10 and a heat transfer duct 20. The base 10 is a good heat conductive element made of aluminum, copper, graphite or the like. The base 10 is mounted onto an electronic device and has one or more coupling portion 11 on the surface of the base 10 to form a trough seat. The coupling portion 11 has a housing space with a flat bottom. Each coupling portion 11 can receive insertion of the heat transfer duct 20 to form a tight coupling. The heat transfer duct 20 has a pointed distal end 21. Before mounting of the heat transfer duct 20 a soldering paste 30 is disposed into the coupling portion 11, then the heat transfer duct 20 is inserted. The soldering paste 30 may contain tin. As the bottom of the housing space in the coupling portion 11 is flat, when the pointed distal end 21 of the heat transfer duct 20 is inserted, an extra space is formed inside to hold the soldering paste 30. When all the preparation tasks for coupling and soldering are ready, the base 10 is heated to a temperature higher enough to melt the soldering paste 30, the liquid type soldering paste 30 can evenly adsorb to the inner wall 111 of the coupling portion and the pointed distal end 21 of the heat transfer duct 20. As the heat transfer duct 20 and the coupling portion 11 are two separated elements, a layer of air is existed between the two. The liquid type soldering paste 30 can fully fill the void between the inner wall 111 of the coupling portion and the pointed distal end 21 of the heat transfer duct 20 due to capillary action. When the soldering paste 30 is cooled at a lower temperature and solidified, the heat transfer duct 20 and the base 10 are coupled tightly and become integrated. Hence the heat generated by the electronic device can be directly transmitted to the heat transfer duct 20 and dispelled to achieve the heat dissipating effect. Moreover, as the heat transfer duct 20 is mounted vertically onto the base 10, the contact area with the air increases, and the heat dissipating efficiency improves.

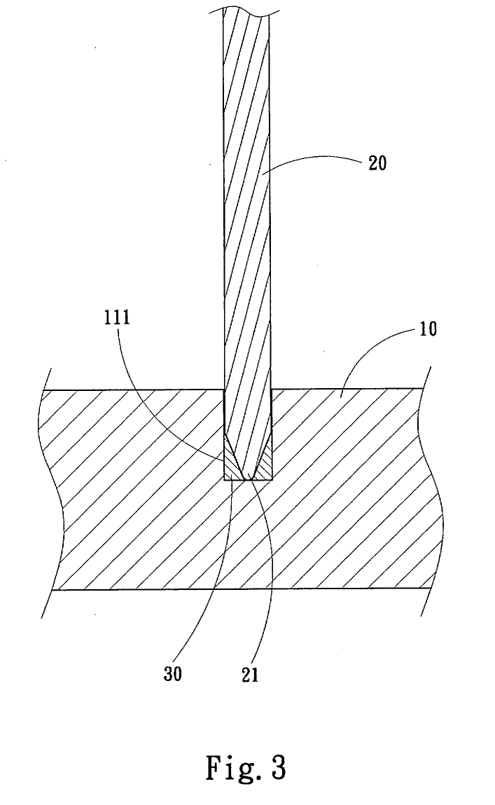

Refer to FIG. 3 for a second embodiment of the invention. The base 10 has a sufficient thickness to allow the coupling portion 11 to be formed thereon at a desired depth to become a trough. The heat transfer duct 20 is inserted into the coupling portion 11 to form a tight coupling. The heat transfer duct 20 and the base 10 are soldered through the soldering paste 30 to become integrated. Therefore fast heat dissipation can be achieved.

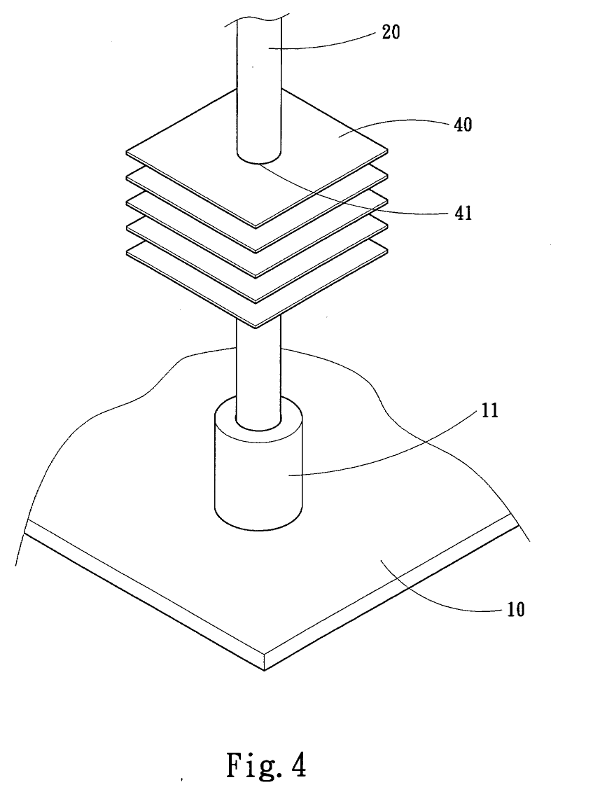

Refer to FIG. 4 for a third embodiment of the invention. This invention can also be used with one or more heat dissipating fins 40. The heat dissipating fin 40 is made of metal and has an opening 41 running though by the heat transfer duct 20. Then they are soldered together through the soldering paste 30. Such a structure can greatly increase the contact area with the air to enhance the heat dissipating efficiency.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A heat transfer duct fastening structure, comprising:
a heat transfer duct having a pointed distal end; and
a base which is heat conductive and has a coupling portion, the coupling portion having a housing space which has a flat bottom to receive the heat transfer duct to form a tight coupling, the base and the heat transfer duct being soldered together through a soldering paste.

2. The heat transfer duct fastening structure of claim 1, wherein the coupling portion is a trough seat formed on the surface of the base.

3. The heat transfer duct fastening structure of claim 1, wherein the coupling portion is a trough formed on the surface of the base.

4. The heat transfer duct fastening structure of claim 1, wherein the heat transfer duct is coupled with at least one heat dissipating fin.
